(19) United States
(12) Patent Application Publication
(10) Pub. No.: US 2026/0370095 A1
(43) Pub. Date: Nov. 19, 2026

(54) HEAT GENERATION MODULE AND ASSOCIATED ELECTRICAL DEVICE

(71) Applicant: ABB SCHWEIZ AG, Baden (CH)

(72) Inventors: Pei Yan, Shanghai (CN); Qin Wang, Shanghai (CN); Qionghao Zhu, Shanghai (CN); Weimin Li, Shanghai (CN)

(21) Appl. No.: 19/733,461

(22) Filed: Jul. 7, 2026

Related U.S. Application Data
(63) Continuation of application No. PCT/CN2024/082020, filed on Mar. 15, 2024.

(51) Int. Cl. H02K 11/042

(52) U.S. Cl. CPC H02K 11/042

(57) ABSTRACT

Embodiments of the present disclosure relate to a heat generation module including a back plate having a first surface and a second surface opposite to the first surface; and a heat generation component mounted on the first surface; wherein a plurality of grooves are radially arranged on the second surface and constructed to be able to create a fan-like heat dissipation effect while the heat generation module is rotating.

### FIELD OF THE INVENTION

This invention relates to the heat dissipating field, and more particularly, to a heat generation module and its associated electrical device.

### BACKGROUND OF THE INVENTION

Heat dissipating efficiency is very important for some electrical devices, in which heat generation components are generally included. As a non-limited example, diodes are heat generation components and are widely used. The heat dissipation issue may have huge influence for the performance and/or lifetime of the electrical device.

Generators including e.g., synchronous generators are devices designed to convert the mechanical power output of e.g., steam turbines, gas turbines, reciprocating engines and hydro turbines into electrical power for the grid. Typically, generators may comprise a diode module for rectifying current as its key component.

### SUMMARY OF THE INVENTION

The invention is defined by the claims.

According to one aspect of the disclosure, there is provided a heat generation module comprising: a back plate having a first surface and a second surface opposite to the first surface; and a heat generation component mounted on the first surface; wherein a plurality of grooves are radially arranged on the second surface and constructed to be able to create a fan-like heat dissipation effect while the heat generation module is rotating.

Those skilled in the art would appreciate that the plurality of grooves may increase the total dissipation area. Also, the fan-like heat dissipation effect created by the plurality of grooves may help to increase the dissipation efficiency.

In some embodiments, the heat generation module is a diode module and the heat generation component comprises one or more diodes, e.g., for rectifying current.

In some embodiments, the heat generation module is arranged on a rotating unit, e.g., a rotor of a generator.

In some embodiments, the back plate has a thickness in a range from 10 mm to 30 mm. With the selected range of the thickness, the heat dissipation efficiency can be further improved.

In some embodiments, the plurality of grooves have a pitch between any two adjacent grooves and the pitch is not smaller than 3 mm. In this way, the pitch can be more easily manufactured.

In some embodiments, the plurality of grooves are evenly arranged on the second surface. In some other embodiments, the plurality of grooves being unevenly arranged is also possible.

According to another aspect of the disclosure, there is provided an electrical device comprising: a rotating unit; and one or more heat generation module of the previous aspect, wherein the one or more heat generation module is configured to rotate with the rotation of the rotating unit.

In some embodiments, the electrical device may further comprise: a mounting component configured to be mounted on a rotating shaft of the rotating unit; wherein the one or more heat generation module is mounted on the mounting component. With the mounting component, the heat generation module can be easily attached to the rotating unit.

In some embodiments, the mounting component is an annular plate having a central hole, and the annular plate can be permanently or detachably fixed onto the rotating shaft via the central hole.

In some embodiments, the back plate of the one or more heat generation module is mounted onto the annular plate. In some embodiments, the back plate may be directly contact the surface of the annular plate.

In some embodiments, the back plate of the one or more heat generation module is spaced from the annular plate via a spacer. With the spacing between the back plate and the annular plate, air flow can be more easily enter the plurality of grooves, thereby improving the heat dissipation effect.

In some embodiments, the one or more heat generation module comprises two rotatable heat generation modules, which are symmetrical about a rotating shaft of the rotating unit.

In some embodiments, the one or more heat generation module comprises one or more diode modules, which may serve as a rectifying circuit.

In some embodiments, the electrical device is a generator and the rotating unit is a rotor.

### BRIEF DESCRIPTION OF THE DRAWINGS

In the drawings, similar/same reference signs throughout different views generally represent similar/same parts. Drawings are not necessarily on scale. Rather, emphasis is placed upon the illustration of the principles of the present invention. In these drawings:

FIG. 1 illustrates a perspective view of a heat generation module according to one embodiment of the present disclosure;

FIG. 2 illustrates another perspective view of the heat generation module of FIG. 1;

FIG. 3 illustrates a rear view of the heat generation module of FIG. 1;

FIG. 4 illustrates a perspective view of a heat generation module mounted on a rotating unit according to one embodiment of the present disclosure;

FIG. 5 illustrates another perspective view of a heat generation module mounted on a rotating unit according to one embodiment of the present disclosure;

FIG. 6 illustrates yet another perspective view of a heat generation module mounted on a rotating unit according to one embodiment of the present disclosure; and

FIG. 7 illustrates a side view of a heat generation module mounted on a rotating unit according to one embodiment of the present disclosure.

### DETAILED DESCRIPTION OF THE EMBODIMENTS

Embodiments of the present disclosure will be described in more details with reference to the drawings. Although the drawings illustrate some embodiments of the present disclosure, it should be appreciated that the present disclosure can be implemented in various manners and should not be interpreted as being limited to the embodiments explained herein. On the contrary, the embodiments are provided to understand the present disclosure in a more thorough and complete way. It should be appreciated that drawings and embodiments of the present disclosure are only for exemplary purposes rather than restricting the protection scope of the present disclosure.

In the descriptions of the embodiments of the present disclosure, the term “includes” and its variants are to be read as open-ended terms that mean “includes, but is not limited to.” The term “based on” is to be read as “based at least in part on.” The terms “one embodiment” and “this embodiment” are to be read as “at least one embodiment.” The following text also can comprise other explicit and implicit definitions.

As stated above, heat dissipating efficiency is very important for some devices. Particularly, it is found that a generator including a conventional diode module for e.g., rectifying the current may suffer a heat dissipating issue. For example, the temperature for the conventional diode module may be quite high, even the rotor current is lower than its permitted current. The heat dissipating issue may result in high risk of the diode module and thus the performance of the generator.

The present disclosure aims to improve the heat dissipating efficiency of the diode module and thus the performance of the generator. However, it should be understood that the present application is not so limited to the diode module and then the generator. Instead, the present application may apply to various heat generation modules and the associated electrical devices comprising the same, i.e., including but not limited to the generator.

According to the present disclosure, an improved heat generation module is provided, comprising: a back plate having a first surface and a second surface opposite to the first surface; and a heat generation component mounted on the first surface; wherein a plurality of grooves are radially arranged on the second surface and constructed to be able to create a fan-like heat dissipation effect while the heat generation module is rotating. Those skilled in the art will appreciate that when the heat generation module is rotating, the fan-like heat dissipation effect created by the plurality of grooves formed on the back plate can greatly improve the heat dissipation of the heat generation module. As a result, the temperature of the heat generation module can be reduced within a desired range.

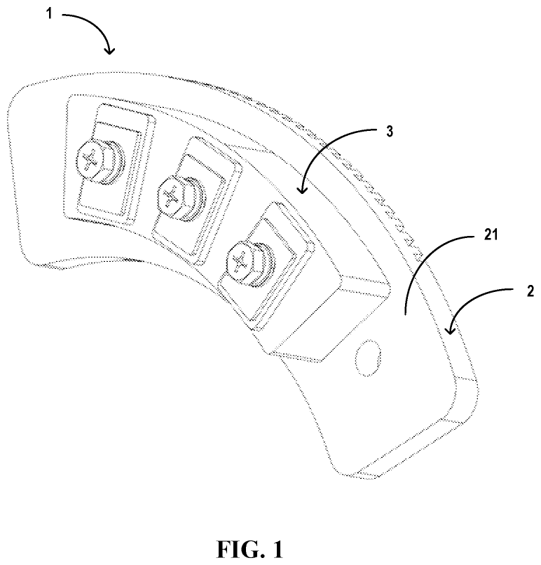

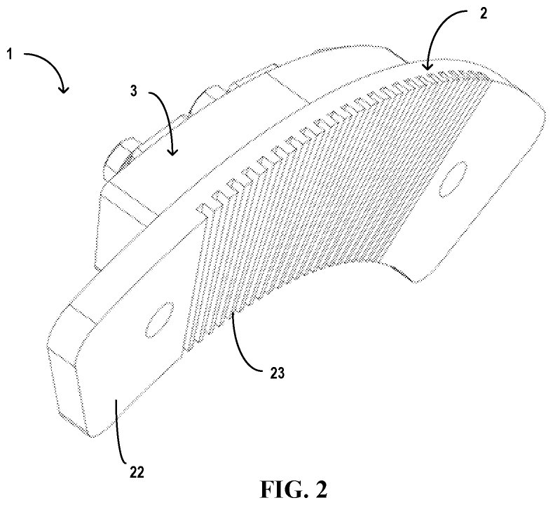

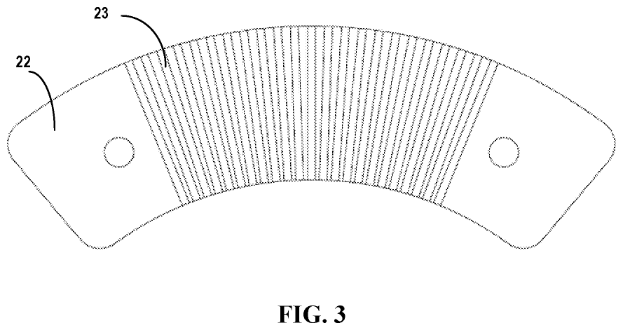

For better understanding of the present application, FIG. 1 illustrates a perspective view of a heat generation module according to one embodiment of the present disclosure; FIG. 2 illustrates another perspective view of the heat generation module of FIG. 1; FIG. 3 illustrates a rear view of the heat generation module of FIG. 1.

As shown in FIGS. 1 and 2, the heat generation module 1 may comprise a back plate 2 and a heat generation component 3 mounted on the back plate 2. Typically, the back plate 2 has a first surface 21 on which the heat generation component 3 is mounted, and a second surface 22 opposite to the first surface 21.

Generally, the heat generation module 1 is used in an electrical device including but not limited to e.g., a generator, and the heat generation component 3 comprised therein may produce heat during its operation. For some application scenarios, the heat generated from the heat generation component 3 might cause great heat related problem if the heat is not properly dissipated.

Just as an example, the heat generation module 1 may be used in a generator (e.g., a synchronous generator) and the heat generation component 3 may comprise a shell and one or more diodes (e.g., formed as a rectifying circuit) within the shell. The diodes are known for its stability and long lifetime, but also for its heat dissipation issue.

In order to facilitate the heat dissipation, the back plate 2 is made of metal material or other heat conducting material, wherein the metal material may include but do not limit to copper, iron, etc. and other heat conducting material may include but do not limit to ceramic material.

With the heat conducting material as the back plate, those skilled in the art would appreciate that heat generated from the heat generation component 3 can be easily conducted towards the back plate 2 and then dissipated towards its surrounding environment.

Further, in order for a better heat dissipation effect, in some embodiments the first surface of the back plate 2 may be larger than the footprint of the heat generation component 3. In some embodiments, the back plate 2 may at least enclose and physically contact the bottom surface of the heat generation component 3. In some embodiments, the back plate 2 may have a thickness of more than 10 mm, preferably in the range from 10 mm to 30 mm.

Particularly, in the case that the heat generation module 1 is configured to be rotatable within an electrical device (e.g., the heat generation module 1 being mounted on a rotating unit), as shown in FIGS. 2 and 3, the back plate 2 may be further constructed with a plurality of grooves 23, wherein in some embodiments, the plurality of grooves 23 are radially arranged on the second surface 22 of the back plate 2, i.e., each extending in the radial direction. Typically, the radial direction of the plurality of grooves 23 is arranged perpendicular to an axis (not shown) around which the heat generation module 1 is configured to be rotated during operation.

With the above arrangements, those skilled in the art would appreciate that the plurality of grooves 23 will greatly increase the heat dissipation area. Further, due to the radial arrangement of the plurality of grooves 23, when the heat generation module 1 is rotating around the axis during operation, the plurality of grooves 23 will rotate with the back plate 2 of the heat generation module 1. In this case, the rotation of the plurality of grooves 23 may create a fan-like heat dissipation effect, which will greatly improve the heat dissipation effect for the heat generation module 1.

To further improve the heat dissipation effect, in some embodiments the plurality of grooves may be distributed across the whole second surface 22. However, this is not a limitation, in some other embodiments, the plurality of grooves being simply distributed across part of the second surface 22 is also possible.

In some embodiments, the plurality of grooves 23 may have a pitch between any two adjacent grooves 23 and the pitch may be as smaller as about 3 mm or have a minimum central angle of about 2 degrees. That means that the plurality of grooves are very closely arranged, which may help to increase the heat dissipation area. Of course, in some other embodiments, the pitch larger than 3 mm or the corresponding central angle larger than 2 degrees is also possible, and in such a case the pitch can be more easily manufactured.

In some embodiments, the plurality of grooves may be evenly arranged on the second surface, which may also help to increase the heat dissipation efficiency. Of course, in some other embodiments the plurality of grooves being unevenly arranged on the second surface is also possible.

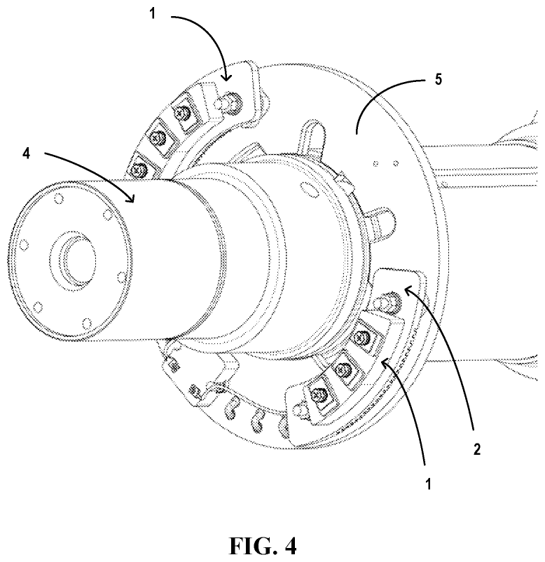

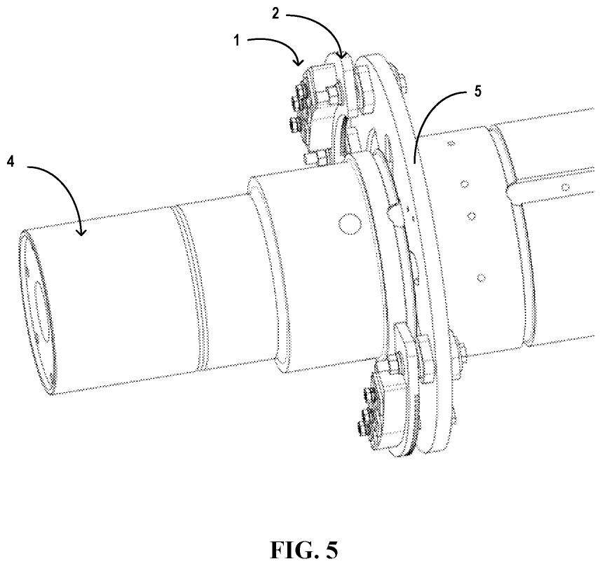

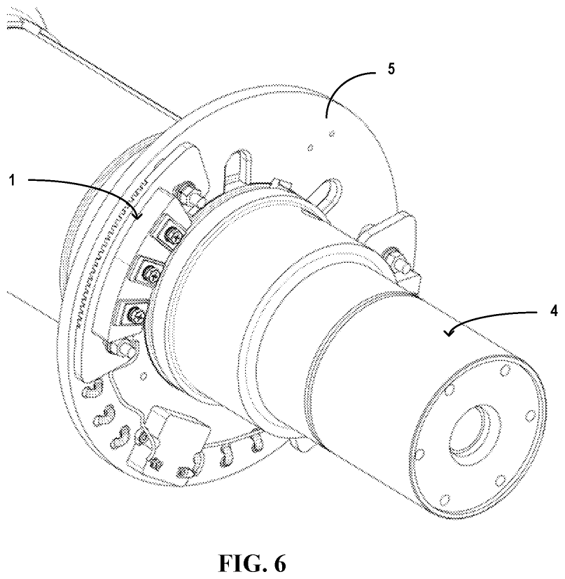

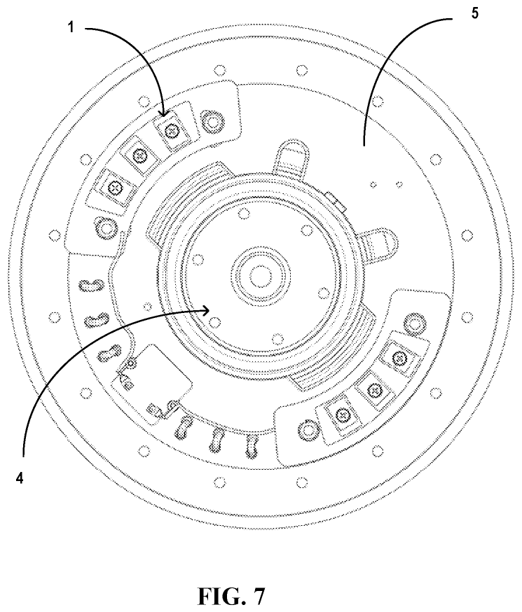

For better understanding the application scenario of the heat generation module 1, FIG. 4 illustrates a perspective view of a heat generation module mounted on a rotating unit according to one embodiment of the present disclosure; FIG. 5 illustrates another perspective view of a heat generation module mounted on a rotating unit according to one embodiment of the present disclosure; FIG. 6 illustrates yet another perspective view of a heat generation module mounted on a rotating unit according to one embodiment of the present disclosure; and FIG. 7 illustrates a side view of a heat generation module mounted on a rotating unit according to one embodiment of the present disclosure.

As shown in FIGS. 4-7, the heat generation module 1 with the back plate 2 and the heat generation component 3 is arranged on a rotating unit 4. Typically, in the case that the heat generation module 1 is applied in e.g., a generator, the heat generation module 1 may be a diode module and the rotating unit 4 may be a rotor of the generator, wherein the diode module may be used as a rectifying circuit (e.g., a rectifying bridge) for e.g., rectifying the AC current into the DC current and supply the DC current to the rotor.

To facilitate the mounting of the heat generation module 1, in some embodiments a mounting component 5 is provided, which is configured to be e.g., mounted on a rotating shaft of the rotating unit 4. Then one or more heat generation modules 1 may be mounted on the surface of the mounting component 5 via various connecting means (e.g., a screw), with the second surface of the back plate facing the mounting component 5.

In some embodiments, the mounting component 5 may be an annular plate with a central hole and may be permanently or detachably fixed onto the rotating shaft via the central hole. In this case, one or more heat generation modules 1 may be mounted on the surface of the annular plate via e.g., one or more screws, with the second surface of the back plate facing the annular plate.

To facilitate the air flow entering the plurality of grooves 23, as shown in FIG. 5, in some embodiments the one or more heat generation modules 1 may be spaced from the annular plate via a spacer, e.g., a gasket or a screw nut. However, this is not a limitation, in some other embodiments, the back plates of the one or more heat generation modules 1 directly contacting the surface of the annular plate is also possible.

In the case of a generator (e.g., a synchronous generator), as shown in FIGS. 4-7, the one or more heat generation modules 1 may comprise two heat generation modules, which may be symmetrically mounted onto the rotating unit (e.g., a rotor). Particularly, the one or more heat generation modules may serve as e.g., a 3-phase rectifying bridge for converting an AC input supply into a fixed DC supply. Further, the output of the two heat generation modules may be respectively connected to a positive terminal and a negative terminal for the rotating unit (e.g., a rotor).

With the above arrangements, those skilled in the art would appreciate that the one or more heat generation modules will rotate with the rotating unit during the operation of the generator. As the black plate of the heat generation module of the present disclosure is configured with a plurality of grooves, then as long as the black plate is rotated, the plurality of grooves may behave like a fan, thereby creating a fan-like heat dissipation effect.

For proving the above improved heat dissipation effect, a comparison test is conducted between a heat generation module of the present disclosure (i.e., having a back plate with the plurality of grooves) and a conventional heat generation module (i.e., having a conventional back plate without the plurality of grooves). It is demonstrated that during operation, under the same rotor current of e.g., 238 A, the temperature of the back plate of the present disclosure may be reduced to 99 °C, as compared to 154 °C of the conventional back plate. This is a huge reduction of the temperature.

Those skilled in the art would further appreciate that with the great heat dissipation effect, the failure risk of the heat generation module (e.g., the diode modules) can be reduced. In addition, since the temperature of the present disclosure can be reduced as compared to the conventional design, a higher rated current for the rotating unit (e.g., the rotor) may be applied. Also, the cost for an electrical device with a higher rated current can be reduced.

Variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A heat generation module comprising:
a back plate having a first surface and a second surface opposite to the first surface; and
a heat generation component mounted on the first surface;
wherein a plurality of grooves are radially arranged on the second surface and constructed to be able to create a fan-like heat dissipation effect while the heat generation module is rotating.

2. The heat generation module of claim 1, wherein the heat generation module is a diode module and the heat generation component comprises one or more diodes.

3. The heat generation module of claim 1, wherein the heat generation module is arranged on a rotating unit.

4. The heat generation module of claim 1, wherein the back plate has a thickness in a range from 10 mm to 30 mm.

5. The heat generation module of claim 1, wherein the plurality of grooves have a pitch between any two adjacent grooves and the pitch is not smaller than 3 mm.

6. The heat generation module of claim 1, wherein the plurality of grooves are evenly arranged on the second surface.

7. An electrical device comprising:
a rotating unit; and
one or more heat generation module of claim 1, wherein the one or more heat generation module is configured to rotate with the rotation of the rotating unit.

8. The electrical device of claim 7, further comprising:
a mounting component configured to be mounted on a rotating shaft of the rotating unit;
wherein the one or more heat generation module is mounted on the mounting component.

9. The electrical device of claim 8, wherein the mounting component is an annular plate having a central hole, and the annular plate is fixed onto the rotating shaft via the central hole.

10. The electrical device of claim 9, wherein the back plate of the one or more heat generation module is mounted onto the annular plate.

11. The electrical device of claim 9, wherein the back plate of the one or more heat generation module is spaced from the annular plate via a spacer.

12. The electrical device of claim 7, wherein the one or more heat generation module comprises two heat generation modules, which are symmetrical about a rotating shaft of the rotating unit.

13. The electrical device of claim 7, wherein the one or more heat generation module is one or more diode modules, which serves as a rectifying circuit.

14. The electrical device of claim 7, wherein the electrical device is a generator and the rotating unit is a rotor.
